(19) United States
(12) Patent Application Publication
(10) Pub. No.: US 2025/0033159 A1
(43) Pub. Date: Jan. 30, 2025

(54) CHEMICAL MECHANICAL POLISHING APPARATUS

(71) Applicant: SAMSUNG ELECTRONICS CO, LTD., Suwon-si (KR)

(72) Inventors: Seyun PARK, Suwon-si (KR); Donghoon KWON, Suwon-si (KR)

(73) Assignee: SAMSUNG ELECTRONICS CO, LTD., Suwon-si (KR)

(21) Appl. No.: 18/662,283

(22) Filed: May 13, 2024

(30) Foreign Application Priority Data
Jul. 28, 2023 (KR) 10-2023-0098801

(51) Int. Cl. B24B 37/20

(52) U.S. Cl. CPC B24B 37/205

(57) ABSTRACT

A chemical mechanical polishing apparatus includes: a platen; a chemical mechanical polishing (CMP) pad on an upper surface of the platen, the CMP pad comprising an installation hole; a polishing head on the platen, the polishing head being configured to bring a wafer W into contact with the CMP pad; a slurry supply unit configured to supply slurry to the CMP pad; and a sensor module in the installation hole of the CMP pad, wherein the sensor module includes: a window at an upper end of the installation hole; a housing below the window, the housing comprising an inclined internal surface; and a sensor below the housing.

### CROSS-REFERENCE TO RELATED APPLICATION

This application claims benefit of priority to Korean Patent Application No. 10-2023-0098801, filed on Jul. 28, 2023, in the Korean Intellectual Property Office, the disclosure of which is incorporated herein by reference in its entirety.

### BACKGROUND

### 1. Field

The disclosure relates to a chemical mechanical polishing apparatus.

### 2. Description of the Related Art

In the manufacturing of semiconductor devices, a chemical mechanical polishing (CMP) process of a CMP apparatus is used to flatten a surface of a wafer. Also, the CMP process polishes the surface of the wafer by using a chemical mechanical interaction between the wafer and a CMP pad.

The polishing degree of the wafer is determined by monitoring through a sensor provided in the CMP apparatus. Here, the sensor detects an acoustic signal generated by a frictional contact between the wafer and the CMP pad. The acoustic signal is weakened while the acoustic signal passes through an encapsulation protective device (EPD) window (formed of polyurethane), and thus, the acoustic signal is not accurately detected by the sensor.

### SUMMARY

Provided are a method and a chemical mechanical polishing apparatus capable of easily detecting an acoustic signal with a sensor.

According to an aspect of the disclosure, chemical mechanical polishing apparatus includes: a platen; a chemical mechanical polishing (CMP) pad on an upper surface of the platen, the CMP pad comprising an installation hole; a polishing head on the platen, the polishing head being configured to bring a wafer W into contact with the CMP pad; a slurry supply unit configured to supply slurry to the CMP pad; and a sensor module in the installation hole of the CMP pad, wherein the sensor module includes: a window at an upper end of the installation hole; a housing below the window, the housing comprising an inclined internal surface; and a sensor below the housing.

According to an aspect of the disclosure, chemical mechanical polishing apparatus includes: a platen; a chemical mechanical polishing (CMP) pad on an upper surface of the platen, the CMP pad comprising an installation hole; a polishing head above the platen, the polishing head being configured to bring a wafer into contact with the CMP pad; a slurry supply unit configured to supply slurry to the CMP pad; and a sensor module in the installation hole of the CMP pad; wherein the sensor module includes: a window at an upper end of the installation hole; a diaphragm below the window; a housing below the diaphragm, the housing having an inclined internal surface; a filler configured to fill an internal area of the housing; and a sensor in the installation hole to be below the filler, the sensor being configured to detect an acoustic wave generated during polishing of the wafer.

### BRIEF DESCRIPTION OF DRAWINGS

The above and other aspects, features, and advantages of the disclosure will be more clearly understood from the following detailed description, taken in conjunction with the accompanying drawings, in which:

FIG. 1 is a schematic view illustrating a chemical mechanical polishing (CMP) apparatus according to an embodiment;

FIG. 2 is a view illustrating an arrangement position of a sensor module of a CMP apparatus according to an embodiment;

FIG. 3 is a cross-sectional view illustrating a portion of a CMP apparatus according to an embodiment;

FIG. 4 is an enlarged view of portion A of FIG. 3;

FIG. 5 is a view illustrating an arrangement position of a sensor module of a CMP apparatus according to an embodiment;

FIG. 6 is a cross-sectional view illustrating a portion of a CMP apparatus according to an embodiment;

FIG. 7 is an explanatory view illustrating an arrangement position of a sensor module of a CMP apparatus according to an embodiment;

FIG. 8 is a cross-sectional view illustrating a portion of a CMP apparatus according to an embodiment;

FIG. 9 is an explanatory view illustrating an arrangement position of a sensor module of a CMP apparatus according to an embodiment; and

FIG. 10 is a cross-sectional view illustrating a portion of a CMP apparatus according to an embodiment.

### DETAILED DESCRIPTION

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

In one or more embodiments of the disclosure described below, a hardware approach is described as an example. However, since the one or more embodiments of the disclosure include technology that uses both hardware and software, the various embodiments of the present disclosure do not exclude a software-based approach.

In the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’. In addition, hereinafter, ‘A’ to ‘B’ means at least one of elements from A (including A) and to B (including B).

The term “couple” and the derivatives thereof refer to any direct or indirect communication between two or more elements, whether or not those elements are in physical contact with each other. The terms “transmit”, “receive”, and “communicate” as well as the derivatives thereof encompass both direct and indirect communication. The terms “include” and “comprise”, and the derivatives thereof refer to inclusion without limitation. The term “or” is an inclusive term meaning “and/or”. The phrase “associated with,” as well as derivatives thereof, refer to include, be included within, interconnect with, contain, be contained within, connect to or with, couple to or with, be communicable with, cooperate with, interleave, juxtapose, be proximate to, be bound to or with, have, have a property of, have a relationship to or with, or the like. The term “controller” refers to any device, system, or part thereof that controls at least one operation. Such a controller may be implemented in hardware or a combination of hardware and software and/or firmware. The functionality associated with any particular controller may be centralized or distributed, whether locally or remotely. The phrase “at least one of,” when used with a list of items, means that different combinations of one or more of the listed items may be used, and only one item in the list may be needed. For example, “at least one of A, B, and C” includes any of the following combinations: A, B, C, A and B, A and C, B and C, and A and B and C, and any variations thereof. The expression “at least one of a, b, or c” may indicate only a, only b, only c, both a and b, both a and c, both b and c, all of a, b, and c, or variations thereof. Similarly, the term “set” means one or more. Accordingly, the set of items may be a single item or a collection of two or more items.

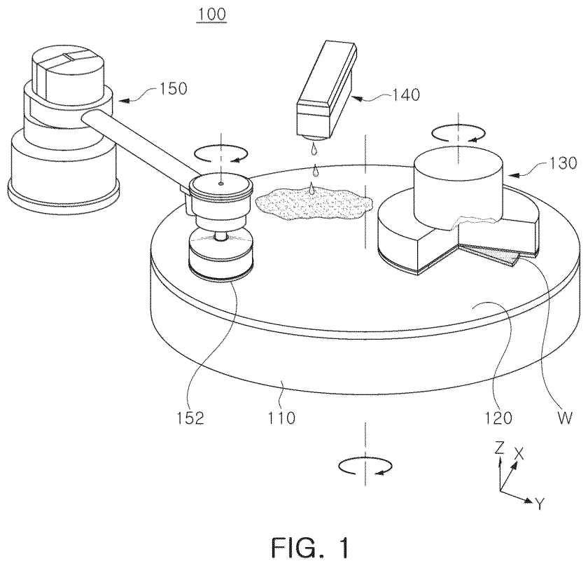

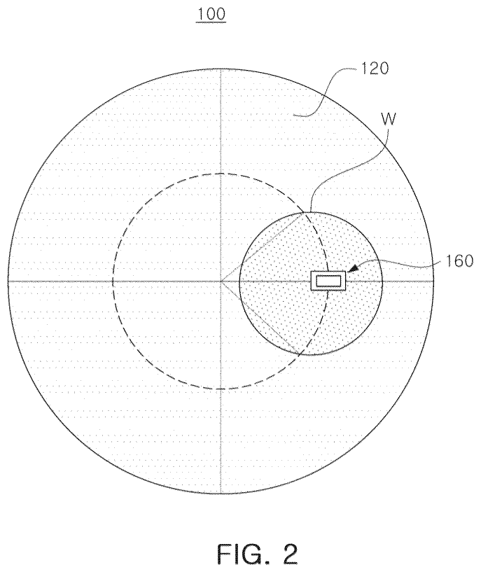

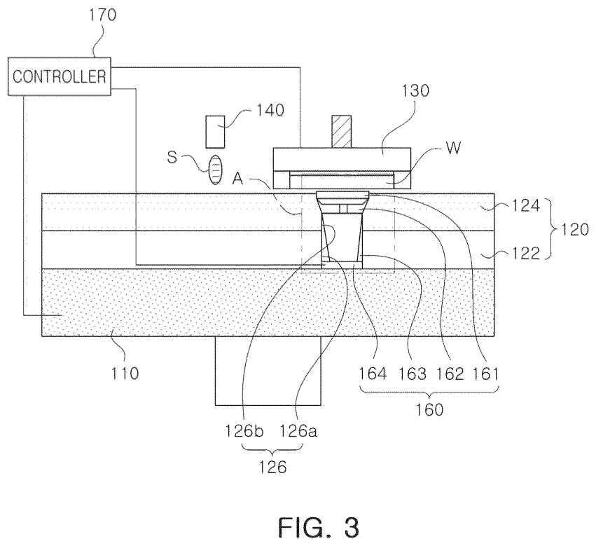

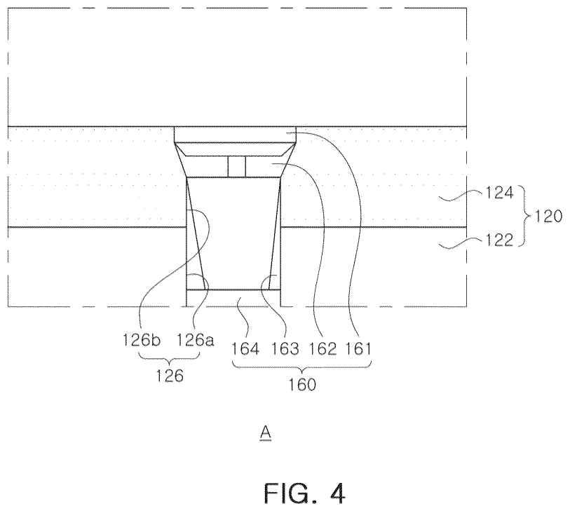

FIG. 1 is a schematic view illustrating a chemical mechanical polishing (CMP) apparatus according to an embodiment. FIG. 2 is a view illustrating an arrangement position of a sensor module of a CMP apparatus according to an embodiment. FIG. 3 is a cross-sectional view illustrating a portion of a CMP apparatus according to an embodiment. FIG. 4 is an enlarged view of portion A of FIG. 3.

Referring to FIGS. 1 to 4, a CMP apparatus 100 according to an embodiment includes a platen 110, a CMP pad 120, a polishing head 130, and a slurry supply unit 140, a conditioning module 150, and a sensor module 160.

The platen 110 may be rotatably installed on a rotating shaft, and an upper end portion of the platen 110 has a circular plate shape. Also, the platen 110 may be rotated in a predetermined direction, for example, counterclockwise. In one embodiment, the CMP pad 120 may be installed on an upper surface of the platen 110.

In an embodiment, as shown in FIG. 3, the CMP pad 120 may include a lower pad 122 disposed on the upper surface of the platen 110 and an upper pad 124 disposed on an upper surface of the lower pad 122. In one embodiment, an installation hole 126 for installing the sensor module 160 may be provided in the lower pad 122 and the upper pad 124. In one embodiment, the installation hole 126 may have a quadrangular shape when viewed from above. In one embodiment, the installation hole 126 may include a first installation hole 126a provided in the lower pad 122 and a second installation hole 126b provided in the upper pad 124. Also, at least one of the lower pad 122 and the upper pad 124 may be a hard polyurethane pad. In one embodiment, a polishing layer for polishing the wafer W may be provided on the upper surface of the upper pad 124.

The polishing head 130 is disposed on the platen 110 and brings a wafer W into contact with the CMP pad 120. In one embodiment, the polishing head 130 may be rotated in a predetermined direction, for example, counterclockwise. Accordingly, the wafer W mounted on a lower surface of the polishing head 130 may contact the CMP pad 120 while being rotated. In this manner, mechanical polishing may be performed while the wafer W is in contact with the CMP pad 120.

The slurry supply unit 140 is configured to supply slurry to the CMP pad 120. In one embodiment, the slurry supply unit 140 may be disposed between the polishing head 130 and the conditioning module 150 in a rotation direction of the platen 110. In an embodiment, the polishing head 130, the conditioning module 150, and the slurry supply unit 140 may be sequentially disposed in the rotation direction of the platen 110. Accordingly, a slurry S supplied from the slurry supply unit 140 may be more smoothly provided to the polishing head 130. In one embodiment, when the CMP process is performed, CMP of the wafer W may be performed using the slurry S supplied from the slurry supply unit 140.

The conditioning module 150 serves to control surface conditions of the CMP pad 120. In one embodiment, the conditioning module 150 may maintain surface roughness of the CMP pad 120 in a constant state by polishing the surface of the CMP pad 120. Also, the conditioning module 150 may polish the CMP pad 120 while polishing the wafer W with the polishing head 130 or may polish the CMP pad 120, while stopping polishing of the wafer W, to restore or maintain the surface roughness of the CMP pad 120. To this end, the conditioning module 150 may include a disk 152 in contact with the CMP pad 120.

The sensor module 160 is installed in the installation hole 126 of the CMP pad 120. In one embodiment, the sensor module 160 may include a window 161 disposed at an upper end of the installation hole 126, a diaphragm 162 disposed below the window 161, a housing 163 installed in the installation hole 126 to be disposed below the diaphragm 162, and a sensor 164 disposed below the housing 163 and on the upper surface of the platen 110.

The window 161 may be formed of a material, different from that of the upper pad 124. For example, the window 161 may be formed of a poreless polymer material. It is possible to control defects, such as scratches, by using a soft polymer, while preventing vibration signal offset due to damping by removing pores from the window 161. For example, the window 161 may be formed of polyurethane or polyvinyl alcohol (PVA).

The diaphragm 162 serves to amplify vibrations. As an example, the diaphragm 162 may be formed of a material, such as metal, metal oxide, or ceramic. As an example, the diaphragm 162 may be formed of a metal oxide material, such as titanium oxide (TiO) or zirconium oxide (ZrO) appropriate for a frequency range of 50 kHz to 1 MHz, which is generated during the polishing of the wafer W.

The housing 163 may be disposed below the diaphragm 162 and may have a funnel-shaped internal surface. Accordingly, the housing 163 may be configured to focus (or collect) acoustic waves generated during the polishing of the wafer W to the sensor 164. In one embodiment, the housing 163 may be formed of silicon or a poreless polyurethane material. In one embodiment, the housing 163 may have an empty internal area.

The sensor 164 is disposed at a lower end of the installation hole 126 and detects the acoustic waves generated during the polishing of the wafer W. Accordingly, the sensor 164 may detect a degree of polishing the wafer W by detecting the frequency of the acoustic wave generated during the polishing of the wafer W. In one embodiment, when the wafer W is formed of a plurality of layers, frequencies of acoustic waves generated during the polishing of the layers formed of different materials may be different from each other. Consequently, the frequencies of acoustic waves detected by the sensor 164 during the polishing of the different layers may be different from each other. Accordingly, the sensor 164 may detect the degree of polishing the wafer W. The sensor 164 may be connected to a controller 170 that may control the operation of the platen 110 and the polishing head 130 according to signals from the sensor 164.

As described above, vibration cancellation due to pores may be prevented through the window 161 formed of a poreless polymer material. In one embodiment, an acoustic wave may be primarily amplified through the diaphragm 162 and, secondarily, amplified by the housing 163. Accordingly, the detection of the acoustic waves by the sensor 164 may be improved.

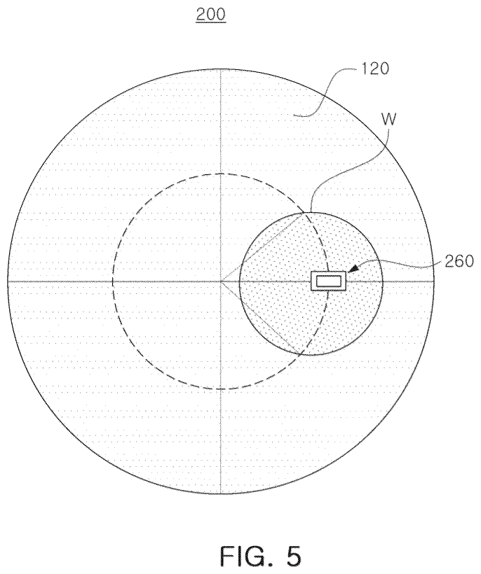

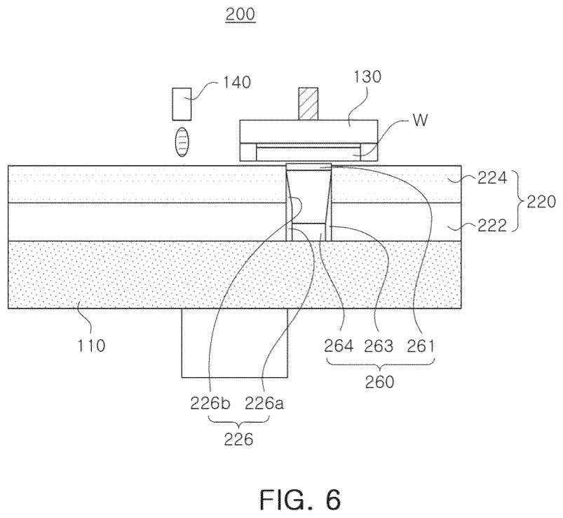

FIG. 5 is a view illustrating an arrangement position of the sensor module 160 of a CMP apparatus according to an embodiment. FIG. 6 is a cross-sectional view illustrating a portion of the CMP apparatus according to an embodiment.

Referring to FIGS. 5 and 6, a CMP apparatus 200 according to an embodiment includes a platen 110, a CMP pad 220, a polishing head 130, a slurry supply unit 140, a conditioning module 150 (refer to FIG. 1), and a sensor module 260.

The platen 110, the CMP pad 220, the polishing head 130, the slurry supply unit 140, and the conditioning module 150 (shown in FIG. 1) are substantially the same as the components described above, and detailed descriptions thereof are omitted here.

The sensor module 260 is installed in an installation hole 226 of the CMP pad 120. In one embodiment, the sensor module 260 includes a window 261 disposed at an upper end portion of the installation hole 226, a housing 263, which is installed in the installation hole 226, to be disposed below the window 261, and a sensor 264 disposed below the housing 263 and on an upper surface of the platen 110. In one embodiment, the installation hole 226 may have a quadrangular shape when viewed from above.

The window 261 may be formed of a material, different from that of the upper pad 224. In one embodiment, the window 261 may be formed of a poreless polymer material. Thus, it is possible to control defects, such as scratches, by using a soft polymer, while preventing vibration signal offset due to damping by removing pores from the window 161. As an example, the window 161 may be formed of polyurethane or polyvinyl alcohol (PVA).

The housing 263 may be disposed below the window 261 and may have a funnel-shaped internal surface. Accordingly, the housing may be configured to focus (or collect) acoustic waves generated during polishing of the wafer W to the sensor 264. In one embodiment, the housing 263 may be formed of silicon or a poreless polyurethane material. In one embodiment, the housing 263 may have an empty internal area.

The sensor 264 is disposed at a lower end of the installation hole 226 and detects an acoustic wave generated during the polishing of the wafer W. Accordingly, the sensor 264 may be configured to detect the degree of polishing of the wafer W by detecting the frequency of an acoustic wave generated during polishing of the wafer W. In one embodiment, when the wafer W is formed of a plurality of layers, frequencies of acoustic waves generated during polishing of the layers formed of different materials may be different from each other. Accordingly, the frequencies of the acoustic waves detected by the sensor 264 vary. Therefore, the sensor 264 may control the degree of polishing of the wafer W.

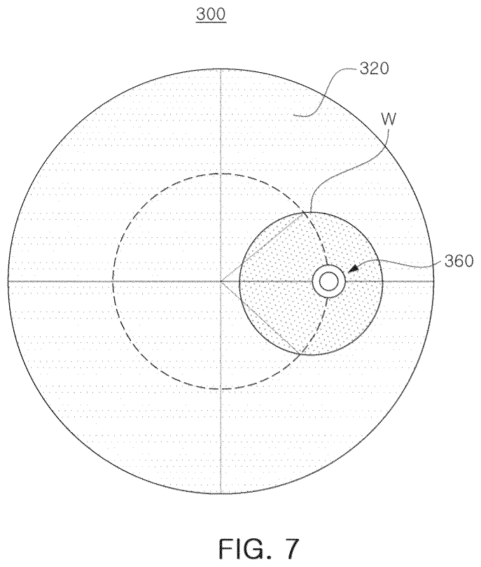

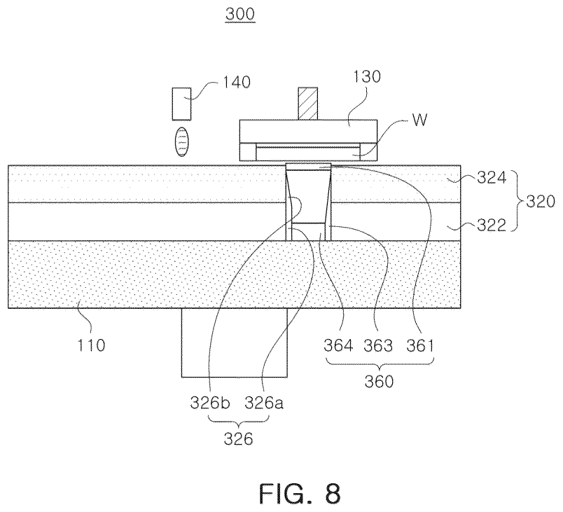

FIG. 7 is a view illustrating an arrangement position of a sensor module of a CMP apparatus according to an embodiment. FIG. 8 is a cross-sectional view illustrating a portion of a CMP apparatus according to an embodiment.

Referring to FIGS. 7 and 8, a CMP apparatus 300 according to an embodiment includes a platen 110, a CMP pad 320, a polishing head 130, a slurry supply unit 140, and a conditioning module 150 (refer to FIG. 1), and a sensor module 260.

The platen 110, the polishing head 130, the slurry supply unit 140, the conditioning module 150 (shown in FIG. 1), and the sensor module 260 (shown in FIG. 6) are substantially the same as the components described above, and detailed descriptions thereof will be omitted here.

For example, as shown in FIG. 8, the CMP pad 320 may include a lower pad 322 disposed on an upper surface of the platen 110 and an upper pad 324 disposed on an upper surface of the lower pad 322. An installation hole 326 for installing the sensor module 260 may be provided in the lower pad 322 and the upper pad 324. In one embodiment, the installation hole 326 may have a circular shape when viewed from above. In one embodiment, the installation hole 326 may include a first installation hole 326a provided in the lower pad 322 and a second installation hole 326b provided in the upper pad 324. Also, at least one of the lower pad 322 and the upper pad 324 may be a hard polyurethane pad. In one embodiment, a polishing layer for polishing the wafer W may be provided on the upper surface of the upper pad 324.

As such, since the installation hole 326 provided in the CMP pad 320 has a circular shape when viewed from above, the housing 263 provided in the sensor module 260 may have a circular funnel shape. Therefore, the installation hole 326 may have a larger area compared to the installation hole 126 shown in FIG. 3.

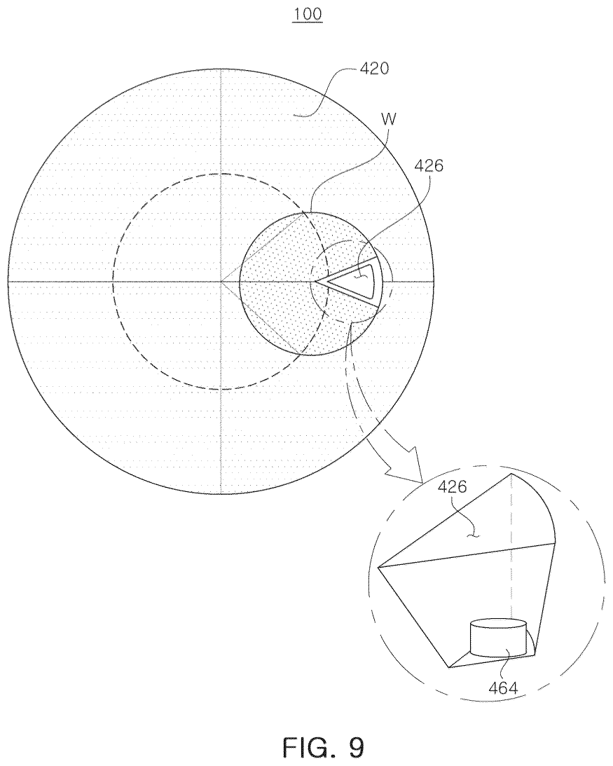

FIG. 9 is a view illustrating an arrangement position of a sensor module of the CMP apparatus according to an embodiment.

Referring to FIG. 9, the CMP pad 420 may have an installation hole 426 in which a sensor 464 is installed. The installation hole 426 may have a fan shape when viewed from above. In one embodiment, an internal surface of the installation hole 426 may have an inverted funnel shape narrowing downwardly. Since a region of an emitted acoustic signal widens toward the edge of the wafer W, a contact area may increase from the center to the edge of the wafer W, which improves an overall acoustic wave detection sensitivity

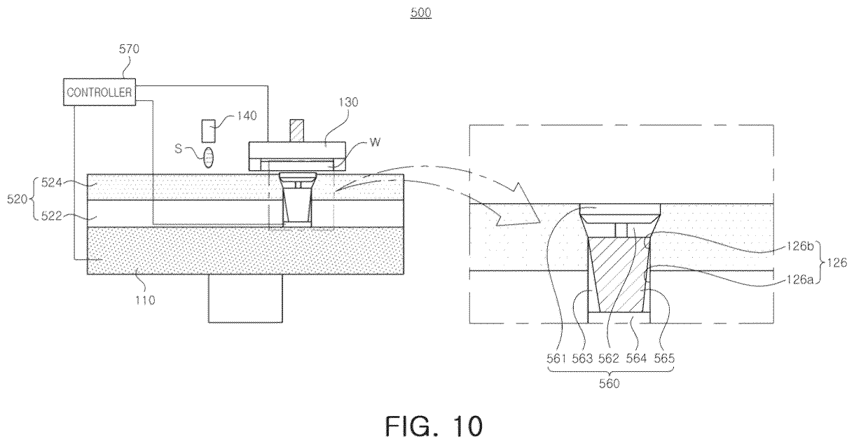

FIG. 10 is a cross-sectional view illustrating a portion of a CMP apparatus according to an embodiment.

Referring to FIG. 10, a CMP apparatus 500 according to an embodiment includes a platen 110, a CMP pad 520, a polishing head 130, a slurry supply unit 140, and a sensor module 560.

The platen 110 may be rotatably installed on a rotating shaft, and an upper end of the platen 110 has a circular plate shape. Also, the platen 110 may be rotated in a predetermined direction, for example, counterclockwise. In one embodiment, the CMP pad 520 may be installed on an upper surface of the platen 110.

In an embodiment, the CMP pad 520 may include a lower pad 522 disposed on the upper surface of the platen 110 and an upper pad 524 disposed on an upper surface of the lower pad 522. An installation hole 526 for installing the sensor module 160 may be provided in the lower pad 522 and the upper pad 524. In one embodiment, the installation hole 526 may include a first installation hole 526a provided in the lower pad 522 and a second installation hole 526b provided in the upper pad 524. Also, at least one of the lower pad 522 and the upper pad 524 may be a hard polyurethane pad. In one embodiment, a polishing layer for polishing the wafer W may be provided on the upper surface of the upper pad 524.

The polishing head 130 is disposed on the platen 110 and brings the wafer W into contact with the CMP pad 120. In one embodiment, the polishing head 130 may be rotated in a predetermined direction, for example, counterclockwise. Accordingly, the wafer W mounted on a lower surface of the polishing head 130 may come into contact with the CMP pad 520 while being rotated. In this manner, mechanical polishing may be performed while the wafer W is in contact with the CMP pad 120.

The slurry supply unit 140 is configured to supply slurry to the CMP pad 120. In one embodiment, the slurry supply unit 140 may be disposed between the polishing head 130 and the conditioning module 150 in accordance with a rotation direction of the platen 110. For example, the polishing head 130, the conditioning module 150, and the slurry supply unit 140 may be sequentially disposed in accordance with the rotation direction of the platen 110. Accordingly, the slurry supplied from the slurry supply unit 140 may be more smoothly provided to the polishing head 130. When the CMP process is performed, CMP of the wafer W may be performed using the slurry supplied from the slurry supply unit 140.

The sensor module 560 is installed in the installation hole 526 of the CMP pad 520. In one embodiment, the sensor module 560 may include a window 561 disposed at an upper end portion of the installation hole 526, a diaphragm 562 disposed below the window 561, a housing 563, which is installed in the installation hole 526, to be disposed below the diaphragm 562, a filler 565 disposed in an internal area of the housing 563, and a sensor 564 disposed between the housing 563 and the platen 110, and disposed on an upper surface of the platen 110.

The window 561 may be formed of a material, which is different from that of the upper pad 524. For example, the window 561 may be formed of a poreless polymer material. Thus, it is possible to control defects, such as scratches, by using a soft polymer, while preventing vibration signal offset due to damping by removing pores from the window 561. For example, the window 161 may be formed of polyurethane or polyvinyl alcohol (PVA).

The diaphragm 562 may be configured to amplify vibrations. For example, the diaphragm 162 may be formed of a material, such as metal, metal oxide, or ceramic. For example, the diaphragm 162 may be formed of a metal oxide material, such as titanium oxide (TiO) or zirconium oxide (ZrO) appropriate for a frequency range of 50 kHz to 1 MHz, which is generated during polishing of the wafer W.

In an embodiment, the housing 563 may be disposed below the diaphragm 562 and may have a funnel-shaped internal surface. Accordingly, the housing 163 may be configured to focus (or collect) acoustic waves generated during polishing of the wafer W to the sensor 564. In one embodiment, the housing 563 may be formed of silicon or a poreless polyurethane material.

The sensor 564 is disposed at a lower end of the installation hole 526 and is configured to detect acoustic waves generated during polishing of the wafer W. Accordingly, the sensor 564 may detect the degree of polishing of the wafer W by detecting the frequency of an acoustic wave generated during polishing of the wafer W. In one embodiment, when the wafer W is formed of a plurality of layers, frequencies of acoustic waves generated during the polishing of the layers (formed of different materials) may be different from each other. Consequently, the frequencies of acoustic waves detected by the sensor 564 during polishing of the different layers may be different from each other. Accordingly, the sensor 564 may detect the degree of polishing of the wafer W. The sensor 564 may be connected to a controller 570 that may control the operation of the platen 110 and the polishing head 130 based on signals from the sensor 564.

The internal area of the housing 563 may be filled with the filler 565. The filler 565 may be solid, and may be formed of materials, such as metal oxide and ceramic, for example. In this manner, the yield of acoustic waves may be improved by filling the internal area of the housing 563 with the solid filler 565.

While embodiments have been illustrated and described above, it will be apparent to those skilled in the art that modifications and variations could be made without departing from the scope of the disclosure as defined by the appended claims.

What is claimed is:

1. A chemical mechanical polishing apparatus comprising:
a platen;
a chemical mechanical polishing (CMP) pad on an upper surface of the platen, the CMP pad comprising an installation hole;
a polishing head on the platen, the polishing head being configured to bring a wafer W into contact with the CMP pad;
a slurry supply unit configured to supply slurry to the CMP pad; and
a sensor module in the installation hole of the CMP pad,
wherein the sensor module includes:
a window at an upper end of the installation hole;
a housing disposed below the window, the housing comprising an inclined internal surface; and
a sensor below the housing.

2. The chemical mechanical polishing apparatus of claim 1, wherein the sensor module further includes a diaphragm between the window and the housing.

3. The chemical mechanical polishing apparatus of claim 1, further comprising a filler configured to fill an internal area of the housing.

4. The chemical mechanical polishing apparatus of claim 1, wherein an internal area of the housing narrows from an upper end portion to a lower end portion.

5. The chemical mechanical polishing apparatus of claim 1, wherein the window comprises a poreless polymer material.

6. The chemical mechanical polishing apparatus of claim 5, wherein the window comprises a polyurethane or polyvinyl alcohol (PVA) material.

7. The chemical mechanical polishing apparatus of claim 2, wherein the diaphragm comprises at least one of metal, metal oxide, and ceramic.

8. The chemical mechanical polishing apparatus of claim 1, wherein the housing comprises silicon or no pore polyurethane material.

9. The chemical mechanical polishing apparatus of claim 3, wherein the filler corresponds to a solid filter.

10. The chemical mechanical polishing apparatus of claim 9, wherein the filler comprises at least one of metal oxide and ceramic.

11. The chemical mechanical polishing apparatus of claim 1, wherein the sensor is configured to detect acoustic waves generated during polishing of the wafer.

12. The chemical mechanical polishing apparatus of claim 1, wherein the sensor is connected to a controller, and
wherein the controller is configured to control an operation of the platen and the polishing head based on a signal from the sensor.

13. The chemical mechanical polishing apparatus of claim 1, wherein the installation hole has a shape of any one of a quadrangle, a circle, and a sector when viewed from above.

14. A chemical mechanical polishing apparatus comprising:
a platen;
a chemical mechanical polishing (CMP) pad on an upper surface of the platen, the CMP pad comprising an installation hole;
a polishing head above the platen, the polishing head being configured to bring a wafer into contact with the CMP pad;
a slurry supply unit configured to supply slurry to the CMP pad; and
a sensor module in the installation hole of the CMP pad;
wherein the sensor module includes:
a window at an upper end of the installation hole;
a diaphragm below the window;
a housing below the diaphragm, the housing having an inclined internal surface;
a filler configured to fill an internal area of the housing; and
a sensor in the installation hole to be below the filler, the sensor being configured to detect an acoustic wave generated during polishing of the wafer.

15. The chemical mechanical polishing apparatus of claim 14, wherein the window comprises a poreless polymer material.

16. The chemical mechanical polishing apparatus of claim 15, wherein the window comprises a polyurethane or polyvinyl alcohol (PVA) material.

17. The chemical mechanical polishing apparatus of claim 14, wherein the diaphragm comprises at least one of metal, metal oxide, and ceramic.

18. The chemical mechanical polishing apparatus of claim 14, wherein the housing comprises silicon or no pore polyurethane material.

19. The chemical mechanical polishing apparatus of claim 14, wherein the filler comprises at least one of metal oxide and ceramic.

20. The chemical mechanical polishing apparatus of claim 14, wherein the installation hole has a shape of any one of a quadrangle, a circle, and a sector when viewed from above.
